(19) United States
(12) Patent Application Publication
(10) Pub. No.: US 2007/0063280 A1
(43) Pub. Date: Mar. 22, 2007

(54) Thin film transistor array substrate

(76) Inventors: Fu-Yuan Shiau, Chiayi City (TW); Chien-Chih Jen, Taipei City (TW); Meng-Chi Liou, Taoyuan City (TW)

Correspondence Address: J.C. Patents, Inc., Suite 250, 4 Venture, Irvine, CA, 92618, US

(21) Appl. No.: 11/246,611

(22) Filed: Oct. 6, 2005

(30) Foreign Application Priority Data
Sep. 21, 2005 (TW) 94132608

(51) Int. Cl. H01L 27/12

(52) U.S. Cl. 257/347

(57) ABSTRACT

A thin film transistor array substrate having a display area and a non-display area is provided. Pixel units, scan lines and data lines are disposed within the display area, and the scan line and data line are electrically connected to the corresponding pixel units. The non-display region has first chip bonding area and at least one first connecting line disposed within the non-display region. Scan line terminals and first bonding pads are disposed within the first chip bonding area. The scan line terminal is electrically connected to the corresponding scan line. The first connecting line is arranged between two of the adjacent chip bonding areas for making the first bonding pads within the adjacent chip bonding areas electrically connect to each other. The first connecting line comprises conductive layers which are electrically connected to one another.

### CROSS-REFERENCE TO RELATED APPLICATION

This application claims the priority benefit of Taiwan application serial no. 94132608, filed on Sep. 21, 2005. All disclosure of the Taiwan application is incorporated herein by reference.

### BACKGROUND OF THE INVENTION

1. Field of the Invention

The present invention generally relates to an array substrate. More particularly, the present invention relates to a thin film transistor array substrate.

2. Description of Related Art

The advancement of multi-media systems in our society depends to a large extent on the progressive development of semiconductor devices and display devices. For the display device, the thin film transistor liquid crystal display (TFT-LCD) having advantages of higher image quality, optimal space efficiency, low power and non-radiation has become the main stream on the market. The TFT-LCD mainly comprises a thin film transistor array substrate, a color filter array substrate and a liquid crystal layer. The fabrication process of the TFT array substrate comprises deposition, photolithography, etching and the like, and these processes would affect the display quality of the LCD device. The TFT array substrate is illustrated in the accompany drawing.

FIG. 1 is a schematic view showing a conventional TFT array substrate. Please refer to FIG. 1, the TFT array substrate 100 has a display region 110 and a non-display region 120. The display region 110 is adapted for displaying image, and the non-display region 120 comprises a plurality of driver ICs for controlling the image. The TFT array substrate 100 comprises a plurality of pixel units 130, a plurality of scan lines 140 and a plurality of data lines 150 within the display region 120. The pixel units 130 are adapted for display image unit; the scan lines 140 and the data lines 150 are electrically connected to the corresponding pixel units 130, and transmit signal to the pixel units 130. Besides, the non-display region 120 comprises a plurality of first chip bonding areas 122 and a plurality of second chip bonding areas 124. The first chip bonding areas 122 comprise a plurality of scan line terminals 142 electrically connected to the corresponding scan lines 140. Similarly, the second chip bonding areas 142 comprise a plurality of data line terminals (not shown) electrically connected to the corresponding data lines 150. After the driver ICs are arranged within the first chip bonding areas 122 and the second chip bonding areas 124, the driver ICs transmit signals to the pixel units 130. Besides, a plurality of bonding pads 160 are arranged within the first chip bonding areas 122, and a plurality of connecting lines 170 are arranged between every neighboring two of the first chip bonding areas 122, to make the bonding pads 160 arranged within every neighboring two of the first chip bonding areas 122 electrically connecting to each other. Each connecting line 170 only comprises a single conductive layer.

FIG. 2A is an enlarged view showing the left hand side of FIG. 1; FIGS. 2B and 2C are schematic cross-sectional views along line A-A′ and B-B′ of FIG. 2A respectively. Please refer to FIGS. 2A, 2B and 2C, the connecting line 170 is formed on a substrate 180 for electrically connecting the bonding pads 160 arranged with every neighboring two of the firs chip bonding areas 122. Generally, a dielectric layer 172 is formed on the connecting line 170 for protection.

With the increased size of the display device, the distance between two of the first chip bonding areas 122 disposed at one end and the other end of the substrate 180 becomes longer. Therefore, the connecting line 170 becomes longer and its resistance becomes larger. If the resistance of the connecting line 170 is extremely large, band mura and horizontal stripe image would occur in the display device, and this would severely affect the display quality of the display device. The connecting line 170 only comprises a single conductive layer for electrical connection. If the connecting line 170 is cut off or separated from the substrate 180 during the fabrication process, the connecting line 170 can not transmit signal, and the display device can not display image anymore.

### SUMMARY OF THE INVENTION

Accordingly, the present invention is directed to a thin film transistor array substrate having connecting lines with lower resistance.

As embodied and broadly described herein, the present invention provides a thin film transistor array substrate having a display region and a non-display region. The non-display region has a plurality of first chip bonding area and a plurality of second chip bonding area. The thin film transistor array substrate comprises a plurality of pixel units, a plurality of scan lines and data lines, a plurality of scan line terminals and data line terminals, a plurality of first bonding pads and at least one first connecting line. The pixel units, the scan lines and data lines are disposed within the display region. The pixel units are adapted for displaying image units. The data lines and the scan lines are electrically connected to the pixel units, to transmit signal to the pixel units. The scan line terminals are disposed within the first chip bonding areas, and each scan line terminal is electrically connected to one of the scan line. The data line terminals are disposed within the second chip bonding areas, and each data line terminal is electrically connected to one of the data line. The first bonding pads are disposed within the first chip bonding areas, and the first connecting line is disposed between two adjacent first chip bonding areas for electrically connecting the first bonding pads disposed within two adjacent first chip bonding areas. The first connecting line comprises a plurality of conductive layers electrically connected to one another.

According to an embodiment of the present invention, thin film transistor array substrate further comprises a plurality of second bonding pads disposed within the second chip bonding areas.

According to an embodiment of the present invention, thin film transistor array substrate further comprises at least one second connecting line disposed between two adjacent second chip bonding areas for electrically connecting the second bonding pads disposed within two adjacent second chip bonding areas. The second connecting line comprises a plurality of conductive layers electrically connected to one another.

According to an embodiment of the present invention, thin film transistor array substrate further comprises at least one third connecting line disposed between the adjacent first chip bonding area and second chip bonding area for electrically connecting the first bonding pad and the second bonding pad. The third connecting line comprises a plurality of conductive layers electrically connected to one another.

According to an embodiment of the present invention, a material of the conductive layers of the first connecting line is selected from the group consisting of Al, Cu, W, Cr, Al alloy, Cu alloy, W alloy, Cr alloy and combinations thereof.

According to an embodiment of the present invention, thin film transistor array substrate further comprises a dielectric layer disposed between two adjacent conductive layers, and the dielectric layer further has a contact window, to make the adjacent conductive layers electrically connecting to each other. The material of the contact window may be the same as that of the upper layer of the two adjacent conductive layers. Besides, the material of the contact window may be different from that of the two adjacent conductive layers.

According to an embodiment of the present invention, the place where the contact window is formed is a concave region. Further, thin film transistor array substrate comprises a plurality of driver ICs arranged within the first chip bonding area, and the driver ICs are lodged in the concave region.

As embodied and broadly described herein, the present invention provides a thin film transistor array substrate having a display region and a non-display region. The non-display region has a plurality of first chip bonding area and a plurality of second chip bonding area. The thin film transistor array substrate comprises a plurality of pixel units, a plurality of scan lines and data lines, a plurality of scan line terminals and data line terminals, a plurality of second bonding pads and at least one second connecting line. The pixel units, the scan lines and data lines are disposed within the display region. The pixel units are adapted for displaying image units. The data lines and the scan lines are electrically connected to the pixel units, to transmit signal to the pixel units. The scan line terminals are disposed within the first chip bonding areas, and each scan line terminal is electrically connected to one of the scan line. The data line terminals are disposed within the second chip bonding areas, and each data line terminal is electrically connected to one of the data line. The second bonding pads are disposed within the second chip bonding areas, and the second connecting line is disposed between two adjacent second chip bonding areas for electrically connecting the second bonding pads disposed within two adjacent second chip bonding areas. The second connecting line comprises a plurality of conductive layers electrically connected to one another.

According to an embodiment of the present invention, the thin film transistor array substrate further comprises a plurality of first bonding pads disposed within the first chip bonding areas.

According to an embodiment of the present invention, the thin film transistor array substrate further comprises at least one third connecting line disposed between the adjacent first and second chip bonding areas for electrically connecting the first and the second bonding pads disposed within the adjacent first and second chip bonding areas. The third connecting line comprises a plurality of conductive layers electrically connected to one another.

According to an embodiment of the present invention, a material of the conductive layers of the second connecting line is selected from the group consisting of Al, Cu, W, Cr, Al alloy, Cu alloy, W alloy, Cr alloy and combinations thereof.

According to an embodiment of the present invention, the thin film transistor array substrate further comprises a dielectric layer disposed between two adjacent conductive layers, and the dielectric layer further has a contact window, to make the adjacent conductive layers electrically connecting to each other. The material of the contact window may be the same as that of the upper layer of the two adjacent conductive layers. Besides, the material of the contact window may be different from that of the two adjacent conductive layers.

According to an embodiment of the present invention, the place where the contact window is formed is a concave region. More specifically, the thin film transistor array substrate further comprises a plurality of driver ICs arranged within the second chip bonding area, and the driver ICs are lodged in the concave region.

The first connecting line, the second connecting line and the third connecting line of the above-mentioned thin film transistor array substrate are composed of a plurality of conductive layers respectively, and therefore the resistance thereof can be lower. Besides, if one of the conductive layers is cut off, other conductive layers may still work and serve for electrical connection.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view showing a conventional TFT array substrate.

FIG. 2A is an enlarged view showing the left hand side of FIG. 1.

FIGS. 2B and 2C are schematic cross-sectional views along line A-A′ and B-B′ of FIG. 2A respectively.

FIGS. 3A˜3E are vertical views showing a thin film transistor array substrate according to several embodiments of the present invention.

FIG. 4A is an enlarged view showing the region X of FIG. 3A.

FIG. 4B is an enlarged view showing the region Y of FIG. 3B.

FIG. 4C is an enlarged view showing the region Z of FIG. 3C.

FIGS. 5A˜5C are schematic cross-sectional views along line A-A′, B-B′ and C-C′ of FIG. 4A respectively.

FIGS. 6A˜6C are schematic cross-sectional views along line A-A′, B-B′ and C-C′ of FIG. 4A respectively.

FIGS. 7A and 7B are schematic cross-sectional views along line A-A′ and B-B′ of FIG. 4A respectively.

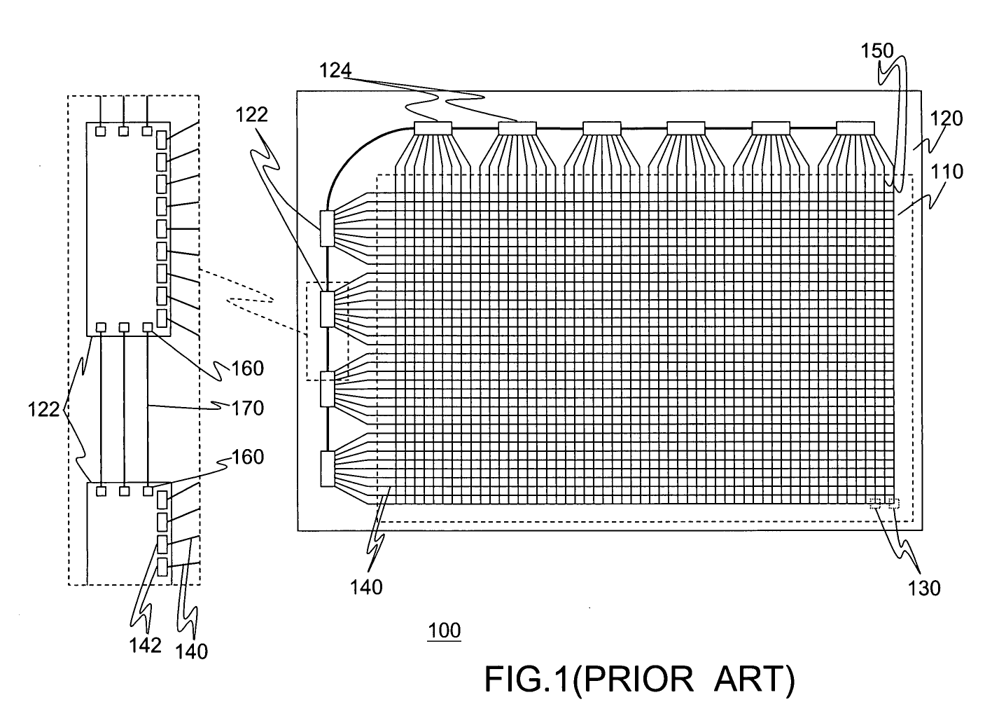

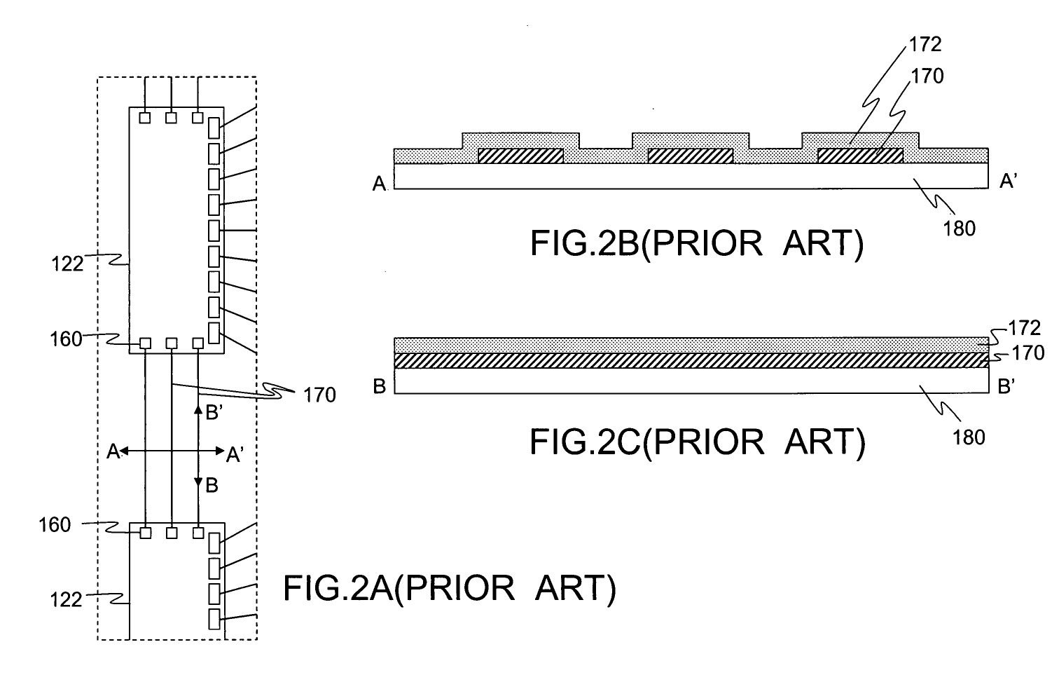

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

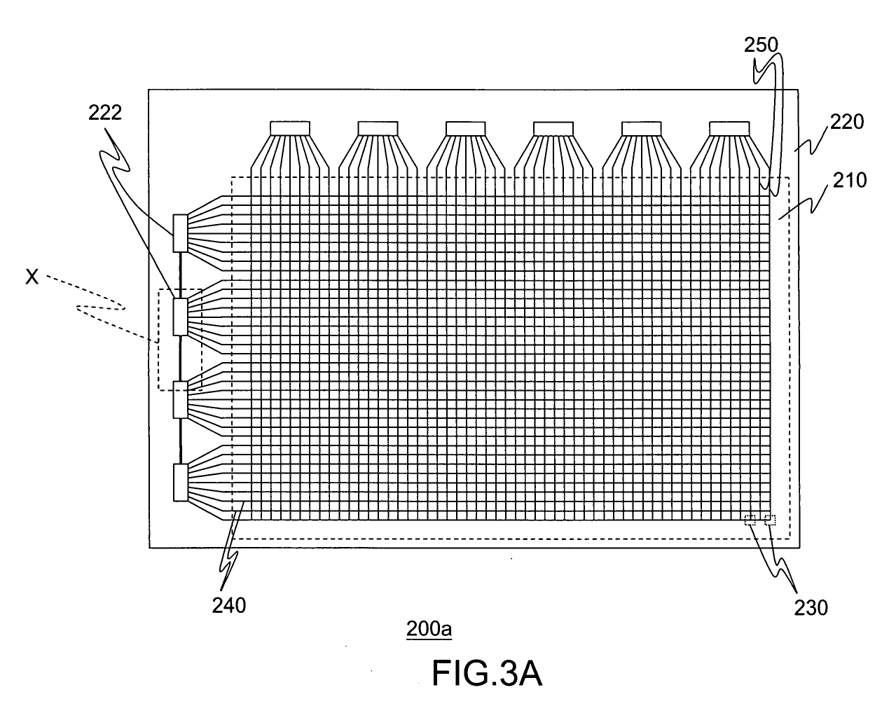

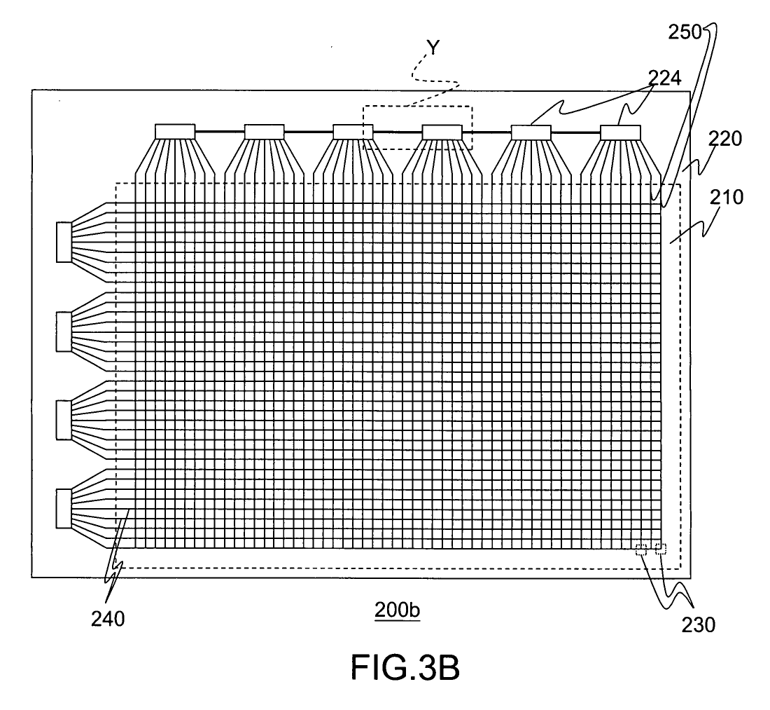

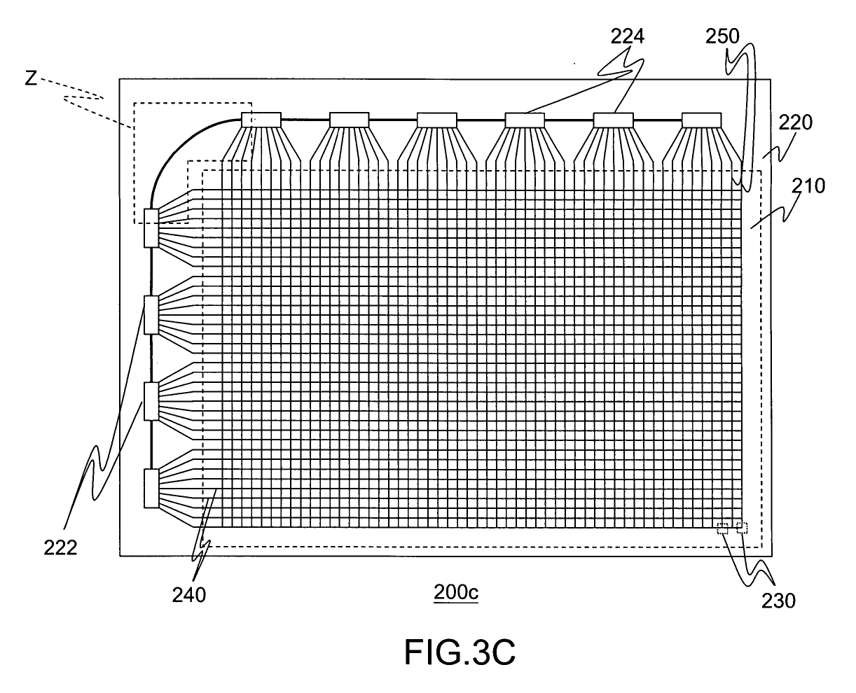

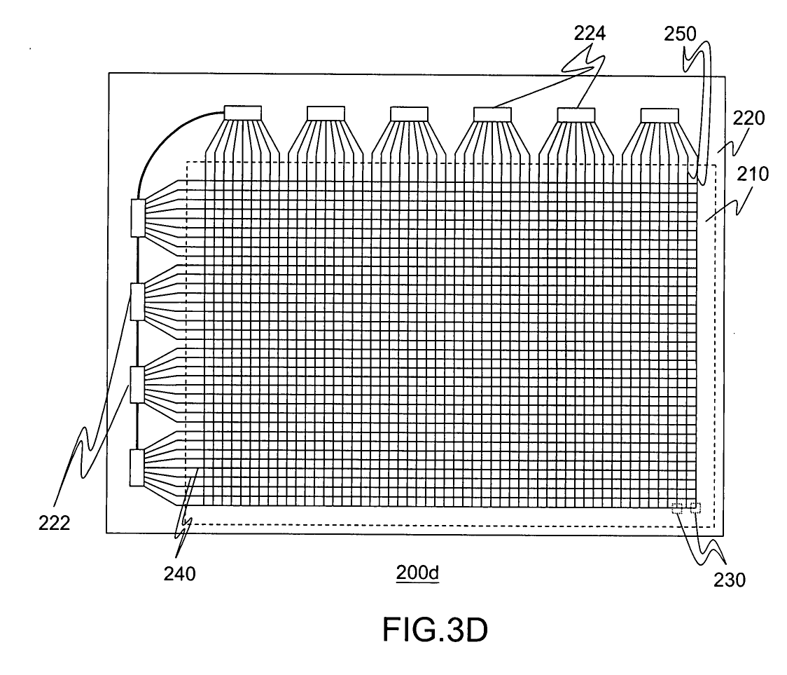

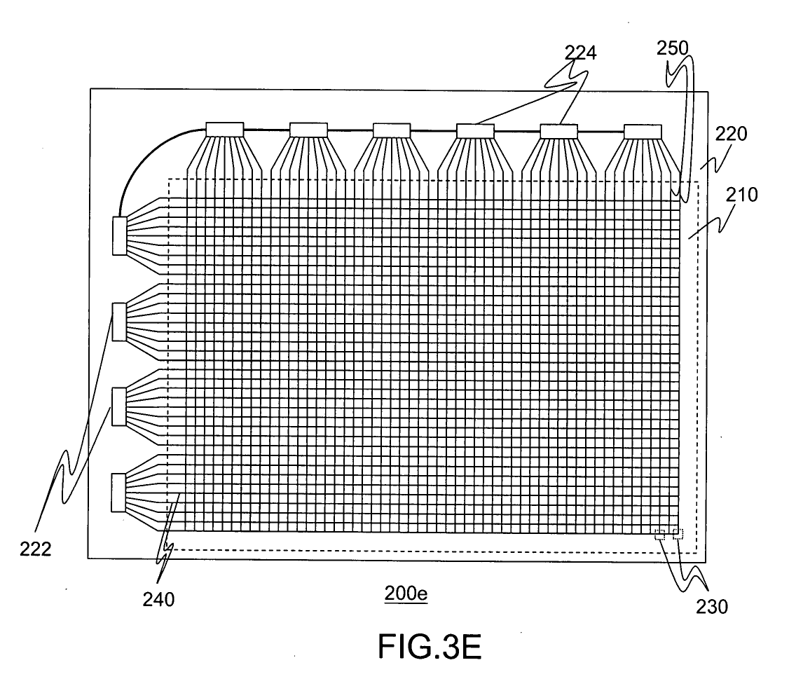

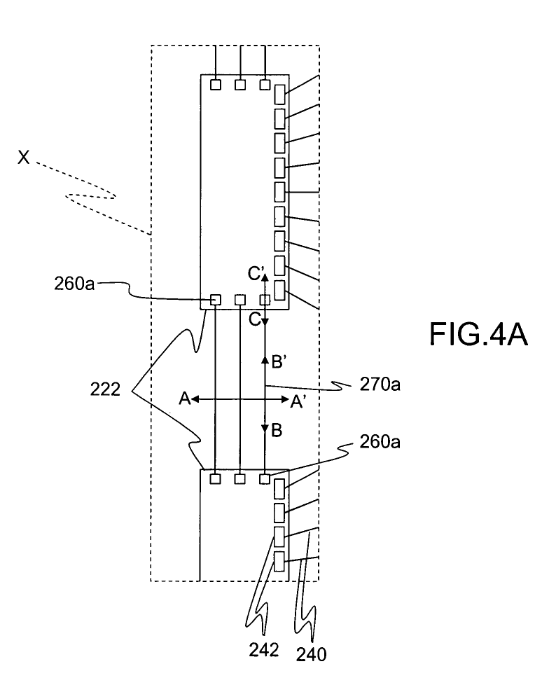

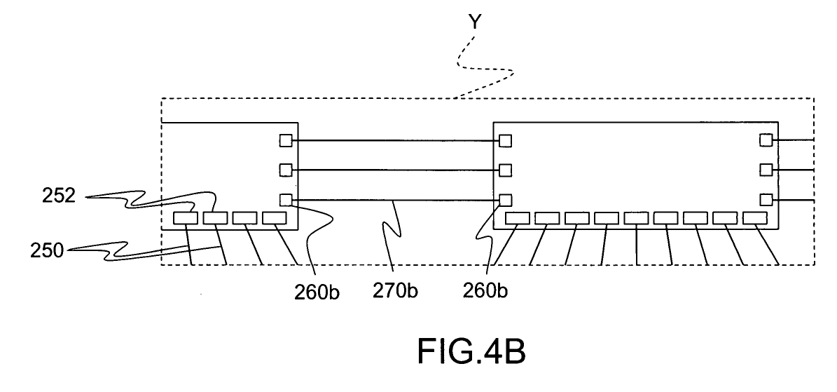

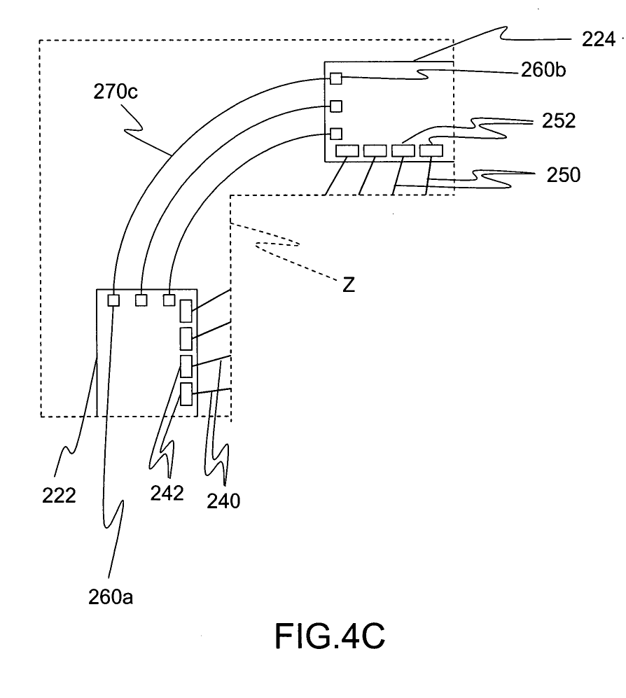

FIG. 3A is a vertical view showing a thin film transistor array substrate according to one embodiment of the present invention. Please refer to FIG. 3A, a thin film transistor array substrate 200a has a display region 210 and a non-display region 220. The display region 210 is adapted for displaying image, and the non-display region 220 comprises a plurality of driver ICs for controlling the image. In the non-display region 220, the thin film transistor array substrate 200 comprises a plurality of pixel units 230, a plurality of scan lines 240 and data lines 250. The pixel units 230 are adapted for displaying image units. The scan lines 240 and the data lines 250 are electrically connected to the corresponding pixel units 230, to transmit signal thereto. Besides, the non-display region 220 has a plurality of first chip bonding areas 222. FIG. 4A is an enlarged view showing the region X of FIG. 3A. Please refer to FIG. 4A, the first chip bonding areas 222 comprises a plurality of scan line terminals 242, and each scan line terminal 242 is electrically connected to the corresponding scan line 240. After a plurality of driver ICs are arranged within the first chip bonding areas 222, the driver ICs transmit signal to the pixel units 230 to control the image. Besides, a plurality of first bonding pads 260a are disposed within the first chip bonding areas 222, and at least one first connecting line 270a is disposed between two adjacent first chip bonding areas 222 for electrically connecting the first bonding pads 260a disposed within two adjacent first chip bonding areas 222. The first connecting line 270a comprises a plurality of conductive layers electrically connected to one another.

FIG. 3B is a vertical view showing a thin film transistor array substrate according to another embodiment of the present invention. The same components shown in FIGS. 3A and 3B are indicated using the same numbers for convenience, and they are not repeated herein. Please refer to FIG. 3B, the non-display region 200 of the thin film transistor array substrate 200b has a plurality of second chip bonding areas 224. FIG. 4B is an enlarged view showing the region Y of FIG. 3B. Please refer to FIG. 4B, a plurality of data line terminals 252 are arranged within the second chip bonding area 242, and each data line terminal 252 is electrically connected to the corresponding data line 250. After a plurality of driver ICs are arranged within the second chip bonding area 224, the driver ICs can transmit signal to the pixel units 230 to control image. Besides, a plurality of second bonding pads 260b are arranged within the second chip bonding area 224, and at least one second connecting line 270b is disposed between two adjacent second chip bonding areas 224 for electrically connecting the second bonding pads 260b disposed within two adjacent second chip bonding areas 224. The second connecting line 270b comprises a plurality of conductive layers electrically connected to one another.

FIG. 3C is a vertical view showing a thin film transistor array substrate according to another embodiment of the present invention. The same components shown in FIGS. 3C, 3A and 3B are indicated using the same numbers for convenience, and they are not repeated herein. Please refer to FIG. 3C, the first connecting line 270a as shown in FIG. 4A is disposed between two adjacent first chip bonding areas 222 of the thin film transistor array substrate 200c, and the second connecting line 270b as shown in FIG. 4B is disposed between two adjacent second chip bonding areas 224. FIG. 4C is an enlarged view showing the region Z of FIG. 3C. Please refer to FIG. 4C, the thin film transistor array substrate 200c further comprises at least one third connecting line 270c. The third connecting line 270c is disposed between the adjacent first chip bonding area 222 and the second chip bonding area 224 for electrically connecting the first bonding pads 260a and the second bonding pads 260b disposed within the adjacent first chip bonding area 222 and the second chip bonding area 224. The third connecting line 270c comprises a plurality of conductive layers electrically connected to one another.

FIGS. 3D and 3E are vertical views showing thin film transistor array substrates according to another two embodiments of the present invention. The same components shown in FIGS. 3D, 3E, 3A˜3C are indicated using the same numbers for convenience, and they are not repeated herein. Please refer to FIG. 3D, the first connecting line 270a as shown in FIG. 4A is arranged between every neighboring two of the first chip bonding areas 222 of the thin film transistor array substrate 200d, and the third connecting line 270c as shown in FIG. 4C is arranged between the adjacent first chip bonding area 222 and second chip bonding area 224. Please refer to FIG. 3E, the second connecting line 270b as shown in FIG. 4B is arranged between every neighboring two of the second chip bonding areas 224 of the thin film transistor array substrate 200e, and the third connecting line 270c as shown in FIG. 4C is arranged between the adjacent first chip bonding area 222 and second chip bonding area 224.

In the above-mentioned embodiments, the first connecting line 270a, the second connecting line 270b or the third connecting line 270c can be selectively arranged on the thin film transistor array substrate 200a, 200b, 200c, 200d and 200e. Therefore, the problem of lower image quality because of higher resistance of the connecting line can be solved by using the connecting line composed of multiple conductive layers.

The multiple conductive layers of the connecting lines are illustrated in the accompanying drawings. For convenience, only the first connecting line is taken as an example for illustration. However, the second and third connecting lines can also be fabricated by using the same method.

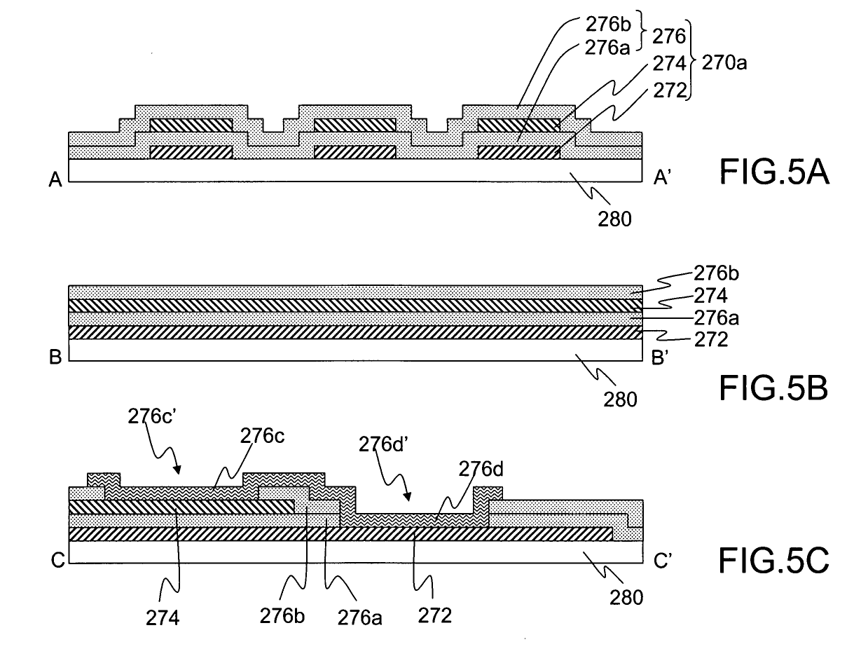

FIGS. 5A˜5C are schematic cross-sectional views along line A-A′, B-B′ and C-C′ of FIG. 4A respectively. Please refer to FIGS. 5A and 5B, the first connecting line 270a comprising a first conductive layer 272, a second conductive layer 274 and a dielectric layer 276 is formed on the substrate 280. The material of the first conductive layer 272 and the second conductive layer 274 is selected from the group consisting of Al, Cu, W, Cr, Al alloy, Cu alloy, W alloy, Cr alloy and combinations thereof. The dielectric layer 276 is disposed between the first conductive layer 272 and the second conductive layer 274. The dielectric layer 276 can be divided into a first dielectric layer 276a and a second dielectric layer 276b according to fabrication sequence. In addition, please refer to FIG. 5C, contact windows 276c and 276d are formed in the dielectric layers 276a and 276b, to make the first conductive layer 272 be electrically connected to the second conductive layer 274. The method of forming the contact windows 276c and 276d is illustrated in the following. First, one contact window opening (not shown) is formed in the first dielectric layer 276a to expose the first conductive layer 272, and the other contact window opening (not shown) is formed in the second dielectric layer 276b to expose the second conductive layer 274. Then, a conductive material is deposited in the above-mentioned contact window openings to form the contact windows 276c and 276d.

In light of the above, the first conductive layer 272 and the second conductive layer 274 are formed in parallel connection, and therefore the resistance of the first connecting line 270a is smaller than that of the conventional connecting line composed of a single conductive layer. As a result, band mura and horizontal stripe image can be avoided by using the first connecting line composed of multiple conductive layers. If the first conductive layer 272 is cut off during fabrication process, the second conductive layer 274 can serve for electrical connection. Otherwise, if the second conductive layer 274 is cut off during fabrication process, the first conductive layer 272 can be adapted for electrical connection. Therefore, the fabrication yield rate can be improved and the cost can be reduced.

It should be noted that concave regions 276c′ and 276d′ are formed on the contact windows 276c and 276d respectively, and therefore driver ICs can be lodged therein to make the driver ICs bond on the thin film transistor array substrate precisely. The structure of the first connecting line is not limited to the above-mentioned structure. The connecting line composed of multiple conductive layers (at least two conductive layers) electrically connected to one another can achieve the purpose of the present invention.

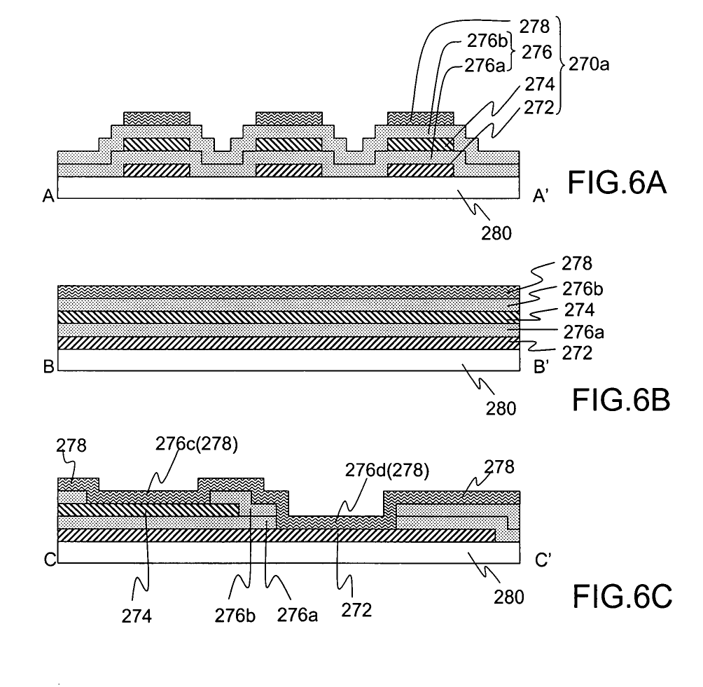

FIGS. 6A˜6C are schematic cross-sectional views along line A-A′, B-B′ and C-C′ of FIG. 4A respectively. Please refer to FIGS. 6A and 6B, the first connecting line 270a comprising a first conductive layer 272, a second conductive layer 274, a dielectric layer 276 and a third conductive layer 278 is formed on the substrate 280. The material of the first conductive layer 272 and the second conductive layer 274 are selected from the group consisting of Al, Cu, W, Cr, Al alloy, Cu alloy, W alloy, Cr alloy and combinations thereof; the material of the third conductive layer 278 can be indium tin oxide (ITO). The dielectric layer 276 is disposed between the first conductive layer 272 and the second conductive layer 274, and it can be divided into a first dielectric layer 276a and a second dielectric layer 276b according to the fabrication sequence. Besides, please refer to FIG. 6C, contact windows 276c and 276d are formed in the dielectric layers 276a and 276b respectively, to make the first conductive layer 272, the second conductive layer 274 and the third conductive layer 278 be electrically connected to one another. The method of forming the contact windows 276c and 276d is illustrated in the following. First, one contact window opening (not shown) is formed in the first dielectric layer 276a to expose the first conductive layer 272, and the other contact window opening (not shown) is formed in the second dielectric layer 276b to expose the second conductive layer 274. Next, a conductive material such as ITO is deposited to form a third conductive layer 278, and the conductive material is deposited in the above-mentioned contact window openings to form the contact windows 276c and 276d. Therefore, the contact window 276c can make the first conductive layer 272, the second conductive layer 274 and the third conductive layer 278 be electrically connected to one another. The material of the contact window 276c can be the same as that of the third conductive layer 278, but is different from that of the first conductive layer 272 or the second conductive layer 274.

In light of the above, the first conductive layer 272, the second conductive layer 274 and the third conductive layer 278 are formed in parallel connection, and therefore the resistance of the first connecting line 270a is smaller than that of the conventional connecting line composed of a single conductive layer. As a result, band mura and horizontal stripe image can be avoided by using the first connecting line composed of multiple conductive layers. If any one of the conductive layers is cut off during fabrication process, other conductive layers can serve for electrical connection. Therefore, the fabrication yield rate can be improved and the cost can be reduced.

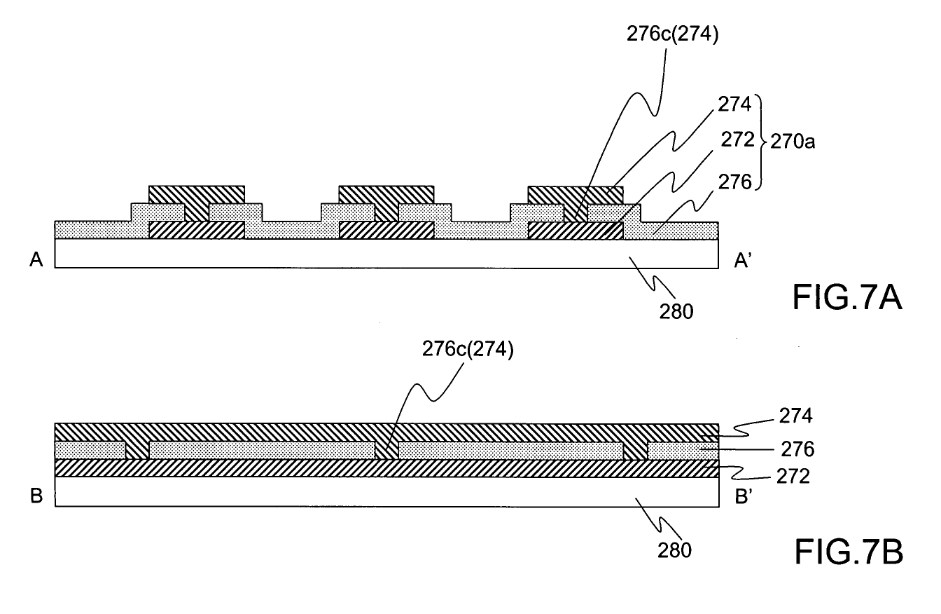

FIGS. 7A and 7B are schematic cross-sectional views along line A-A′ and B-B′ of FIG. 4A respectively. Please refer to FIGS. 7A and 7B, the first connecting line 270a comprising a first conductive layer 272, a second conductive layer 274 and a dielectric layer 276 is formed on the substrate 280. The material of the first conductive layer 272 and the second conductive layer 274 are selected from the group consisting of Al, Cu, W, Cr, Al alloy, Cu alloy, W alloy, Cr alloy and combinations thereof, the dielectric layer 276 is disposed between the first conductive layer 272 and the second conductive layer 274. The contact window 276c is formed in the dielectric layer 276 to make the first conductive layer 272 and the second conductive layer 274 be electrically connected to each other. The method of forming the contact window 276c is illustrated in the following. After the first conductive layer 272 and the dielectric layer 276 are formed, a contact window opening (not shown) is formed in the dielectric layer 276 to expose the first conductive layer 272. Next, the second conductive layer 274 is formed and the contact window opening is filled with the material of the second conductive layer 274 to form the contact window 276c. The first conductive layer 272 is electrically connected to the second conductive layer 274 through the contact window 276c. The material of the contact window 276c is the same as that of the second conductive layer 274.

In summary, the connecting line is composed of a plurality of conductive layers in the present invention. Therefore, the resistance of the connecting line can be lower in order to provide better display quality. Besides, if any one of the conductive layers of the connecting line is cut off, other conductive layers may serve for electrical connection, such that the thin film transistor array substrate can still work. Hence, the fabrication yield rate of the thin film transistor array substrate can be improved and the cost can be reduced. In addition, the concave regions in the connecting lines are adapted for fixing the driver, ICs to prevent the driver ICs from shifting and improve the precision during bonding.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor array substrate, having a display region and a non-display region, the non-display region having a plurality of first chip bonding area and a plurality of second chip bonding area; the thin film transistor array substrate comprising:
a plurality of pixel units disposed within the display region;
a plurality of scan lines and a plurality of data lines disposed within the display region, wherein the data lines and the scan lines are electrically connected to the pixel units;
a plurality of scan line terminals disposed within the first chip bonding areas, wherein each scan line terminal is electrically connected to one of the scan lines;
a plurality of data line terminals disposed within the second chip bonding areas, wherein each data line terminal is electrically connected to one of the data lines;
a plurality of first bonding pads disposed within the first chip bonding areas; and
at least one first connecting line disposed between the adjacent first chip bonding areas for electrically connecting the first bonding pads disposed within the adjacent first chip bonding areas, wherein the first connecting line comprises a plurality of conductive layers electrically connected to one another.

2. The thin film transistor array substrate according to claim 1, further comprising a plurality of second bonding pads disposed within the second chip bonding areas.

3. The thin film transistor array substrate according to claim 2, further comprising at least one second connecting line disposed between the adjacent second chip bonding areas for electrically connecting the second bonding pads disposed within the adjacent second chip bonding areas, wherein the second connecting line comprises a plurality of conductive layers electrically connected to one another.

4. The thin film transistor array substrate according to claim 3, further comprising at least one third connecting line disposed between the adjacent first chip bonding area and second chip bonding area for electrically connecting the first bonding pad and the second bonding pad, wherein the third connecting line comprises a plurality of conductive layers electrically connected to one another.

5. The thin film transistor array substrate according to claim 2, further comprising at least one third connecting line disposed between the adjacent first chip bonding area and second chip bonding area for electrically connecting the first bonding pad and the second bonding pad, wherein the third connecting line comprises a plurality of conductive layers electrically connected to one another.

6. The thin film transistor array substrate according to claim 1, wherein a material of the conductive layers of the first connecting line is selected from the group consisting of Al, Cu, W, Cr, Al alloy, Cu alloy, W alloy, Cr alloy and combinations thereof.

7. The thin film transistor array substrate according to claim 1, further comprising a dielectric layer disposed between two adjacent conductive layers, and the dielectric layer further has a contact window, to make the adjacent conductive layers electrically connecting to each other.

8. The thin film transistor array substrate according to claim 7, wherein the material of the contact window is the same as that of the upper layer of the two adjacent conductive layers.

9. The thin film transistor array substrate according to claim 7, wherein the material of the contact window is different from that of the two adjacent conductive layers.

10. The thin film transistor array substrate according to claim 9, wherein the place where the contact window is formed is a concave region.

11. The thin film transistor array substrate according to claim 10, further comprising a plurality of driver ICs arranged within the first chip bonding area, and the driver ICs are lodged in the concave region.

12. A thin film transistor array substrate, having a display region and a non-display region, the non-display region having a plurality of first chip bonding area and a plurality of second chip bonding area; the thin film transistor array substrate comprising:
a plurality of pixel units disposed within the display region;
a plurality of scan lines and a plurality of data lines disposed within the display region, wherein the data lines and the scan lines are electrically connected to the pixel units;
a plurality of scan line terminals disposed within the first chip bonding areas, wherein each scan line terminal is electrically connected to one of the scan lines;
a plurality of data line terminals disposed within the second chip bonding areas, wherein each data line terminal is electrically connected to one of the data lines;
a plurality of second bonding pads disposed within the second chip bonding areas; and
at least one second connecting line disposed between the adjacent second chip bonding areas for electrically connecting the second bonding pads disposed within the adjacent second chip bonding areas, wherein the second connecting line comprises a plurality of conductive layers electrically connected to one another.

13. The thin film transistor array substrate according to claim 12, further comprising a plurality of first bonding pads disposed within the first chip bonding areas.

14. The thin film transistor array substrate according to claim 13, further comprising at least one third connecting line disposed between the adjacent first and second chip bonding areas for electrically connecting the first and the second bonding pads disposed within the adjacent first and second chip bonding areas, wherein the third connecting line comprises a plurality of conductive layers electrically connected to one another.

15. The thin film transistor array substrate according to claim 12, wherein a material of the conductive layers of the second connecting line is selected from the group consisting of Al, Cu, W, Cr, Al alloy, Cu alloy, W alloy, Cr alloy and combinations thereof.

16. The thin film transistor array substrate according to claim 12, further comprising a dielectric layer disposed between two adjacent conductive layers, and the dielectric layer further has a contact window, to make the adjacent conductive layers electrically connecting to each other.

17. The thin film transistor array substrate according to claim 16, wherein the material of the contact window is the same as that of the upper layer of the two adjacent conductive layers.

18. The thin film transistor array substrate according to claim 16, wherein the material of the contact window is different from that of the two adjacent conductive layers.

19. The thin film transistor array substrate according to claim 18, wherein the place where the contact window is formed is a concave region.

20. The thin film transistor array substrate according to claim 19, further comprising a plurality of driver ICs arranged within the second chip bonding area, and the driver ICs are lodged in the concave region.
